(19) United States
(12) Patent Application Publication
(10) Pub. No.: US 2025/0338497 A1
(43) Pub. Date: Oct. 30, 2025

(54) DOUBLE-SIDED HIGH-K BLOCKING DIELECTRIC

(71) Applicant: Micron Technology, Inc., Boise, ID (US)

(72) Inventors: Marc Aoulaiche, Boise, ID (US); Donghwa Lee, Boise, ID (US); Srinath Venkatesan, Boise, ID (US); Kyubong Jung, Boise, ID (US)

(21) Appl. No.: 19/188,567

(22) Filed: Apr. 24, 2025

Related U.S. Application Data
(60) Provisional application No. 63/639,249, filed on Apr. 26, 2024.

(51) Int. Cl. H10B 43/27; H10B 43/35; H10D 30/01; H10D 30/69; H10D 64/01; H10D 64/68

(52) U.S. Cl. CPC H10B 43/27; H10B 43/35; H10D 30/0413; H10D 30/693; H10D 64/037; H10D 64/685

(57) ABSTRACT

A variety of applications can include one or more memory devices having one or more memory cells containing a blocking dielectric separating a charge trap region from a control gate, where the blocking dielectric includes a high-k dielectric between and contacting a wide bandgap dielectric and the charge trap region. Another high-k dielectric can be positioned contacting the wide bandgap dielectric on a side of the wide bandgap dielectric opposite the side on which the first high-k dielectric is positioned, forming a sandwiched structure. Additional devices, systems, and methods are discussed.

### PRIORITY APPLICATION

This application claims the benefit of priority to U.S. Provisional Application Ser. No. 63/639,249, filed Apr. 26, 2024, which is incorporated herein by reference in its entirety.

### FIELD OF THE DISCLOSURE

Embodiments of the disclosure relate generally to memory devices, and more specifically, to designs of components of the memory devices.

### BACKGROUND

Memory devices are typically provided as internal, semiconductor, integrated circuits in computers or other electronic devices. There are many different types of memory, including volatile and non-volatile memory. Volatile memory requires power to maintain its data, and includes random-access memory (RAM), dynamic random-access memory (DRAM), or synchronous dynamic random-access memory (SDRAM), among others. Non-volatile memory can retain stored data when not powered, and includes flash memory, read-only memory (ROM), electrically erasable programmable ROM (EEPROM), erasable programmable ROM (EPROM), resistance variable memory, such as phase-change random-access memory (PCRAM), resistive random-access memory (RRAM), magnetoresistive random-access memory (M RAM), or three-dimensional (3D) XPoint™ memory, among others.

Flash memory is utilized as non-volatile memory for a wide range of electronic applications. Flash memory devices typically include one or more groups of one-transistor, floating gate or charge trap memory cells that allow for high memory densities, high reliability, and low power consumption. Two common types of flash memory array architectures include NAND and NOR architectures, named after the logic form in which the basic memory cell configuration of each is arranged. The memory cells of the memory array are typically arranged in a matrix. In an example, the gates of each floating gate memory cell in a row of the array are coupled to an access line (e.g., a word line). In a NOR architecture, the drains of each memory cell in a column of the array are coupled to a data line (e.g., a bit line). In a NAND architecture, the drains of each memory cell in a string of the array are coupled together in series, source to drain, between a source line and a data line.

Using 3D architectures for memory devices, such as NAND memory devices, can provide increased capacity over planar structures. The memory arrays for 3D structures can include memory cells arranged as horizontal tiers stacked vertically as strings of memory cells. Design improvements of memory cells can enhance control of operation of the stings of memory cells of a memory device.

### BRIEF DESCRIPTION OF THE DRAWINGS

The drawings, which are not necessarily drawn to scale, illustrate generally, by way of example, but not by way of limitation, various embodiments discussed in the present document.

FIG. 1 represents components of a memory cell, according to various embodiments.

FIG. 2 represents components of another memory cell, according to various embodiments.

FIG. 3 represents a memory device having a string of memory cells, according to various embodiments.

FIG. 4 represents another memory device having a string of memory cells, according to various embodiments.

FIG. 5 is a flow diagram of features of an example method of forming a memory cell, according to various embodiments.

FIG. 6 illustrates a block diagram of an example machine having one or more memory devices having memory cells structured according to various embodiments.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments may be utilized, and structural, logical, mechanical, and electrical changes may be made to these embodiments. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above. Various features can have a vertical component to the direction of their structure. The various embodiments are not necessarily mutually exclusive, as some embodiments can be combined with one or more other embodiments to form new embodiments. The following detailed description is, therefore, not to be taken in a limiting sense.

Both NOR and NAND flash architecture semiconductor memory arrays of flash memory devices are accessed through decoders that activate specific memory cells by selecting an access line (WL) coupled to gates of specific memory cells. In a NOR architecture semiconductor memory array, once activated, the selected memory cells place their data values on data lines, causing different currents to flow depending on the state at which a particular cell is programmed. In a NAND architecture semiconductor memory array, a relatively high bias voltage is applied to a drain-side select gate (SGD) line. Access lines coupled to the gates of the unselected memory cells of each group are driven at a specified pass voltage to operate the unselected memory cells of each group as pass transistors (e.g., to pass current in a manner unrestricted by their stored data values). Current then flows in the line between the source line and the data line through each series-coupled group, restricted only by the selected memory cells of each group, placing current-encoded data values of selected memory cells on the data lines.

Each flash memory cell in a NOR or NAND architecture semiconductor memory array can be programmed individually or collectively to one or a number of programmed states. For example, a single-level cell (SLC) can represent one of two programmed states (e.g., 1 or 0), representing one bit of data. Flash memory cells can also represent more than two programmed states, allowing the manufacture of higher density memories without increasing the number of memory cells, as each cell can represent more than one binary digit (e.g., more than one bit). Such cells can be referred to as multi-state memory cells, multi-digit cells, or multi-level cells (MLCs). In certain examples, MLC has been referred to as a memory cell that can store two bits of data per cell (e.g., one of four programmed states). MLC is used herein in its broader context, to refer to any memory cell(s) that can store more than one bit of data per cell (i.e., that can represent more than two programmed states). Herein, a memory cell that can store two bits of data per cell (e.g., one of four programmed states) is referred to as a dual-level cell (DLC). A triple-level cell (TLC) refers to a memory cell that can store three bits of data per cell (e.g., one of eight programmed states). A quad-level cell (QLC) can store four bits of data per cell, and a penta-level cell (PLC) can store five bits of data per cell.

The distance between tiers of memory cells is referred to as tier pitch. With 3D NAND tier pitch scaling to shorter distances, both program voltage and the cell-to-cell interference drastically increase, degrading the cell performance and reliability. The memory cell can be realized by a floating gate transistor, a charge trap cell, or similar transistor cells. To reduce the short channel effect of the memory cell along with reducing program voltage and cell-to-cell interference, scaling of the thickness of the cell stack can be used. However, this approach is limited by read disturb (RD) and data retention for scaling of bandgap engineered (BE) tunnel structure, by erase performance and trap up for scaling of a blocking oxide (BO) between the charge trap region and corresponding control gate, by program slope and end-of-life for scaling of the charge trap region such as a silicon nitride region.

In various embodiments, a blocking dielectric in a transistor structure can be implemented using a double sided high-k blocking dielectric. The transistor structure can be a memory cell of a memory device. The double sided high-k blocking dielectric can be structured with a wide bandgap dielectric sandwiched between two high-k dielectrics. A high-k dielectric is a dielectric having a dielectric constant greater than the dielectric constant of silion oxide (3.9). The wide bandgap dielectric can be silicon oxide or other dielectric with a wide bandgap that can be used in a memory cell of a memory device that can be subjected to the relatively high program voltages used for memory devices such as NAND devices. Herein, a wide bandgap dielectric is dielectric having a band gap equal or greater than 8.5 eV, which includes silicon dioxide having a bandgap energy of approximately 8.9 eV. The two high_k dielectrics can have substantially the same composition, variations can include differences in stoichiometry. The high-k electric can be, but is not limited to, aluminum oxide, for example Al₂O₃. The double sided high-k blocking dielectric can maintain the physical thickness similar to conventional memory cells, but can scale the equivalent oxide thickness (EOT). Therefore, when the tier pitch is scaled, the program voltage and the cell-to-cell interference can be kept unchanged by centering the cell with an appropriate thickness of the high-k dielectrics. The inventors have applied such a design to product wafers using an Al₂O₃ as the high-k dielectric, showing 300 mV and 175 mV RWB improvement in a read window budget (EWB) for QLC and TLC at time 0, respectively, with this gain maintained until the end of life with respect to no reliability degradation. The EOT quantifies the electrical properties, such as capacitance, of a dielectric in terms of a representative physical thickness. EOT is defined as the thickness of a theoretical silicon dioxide layer that would be required to have the same capacitance density as a given dielectric, ignoring leakage current and reliability considerations.

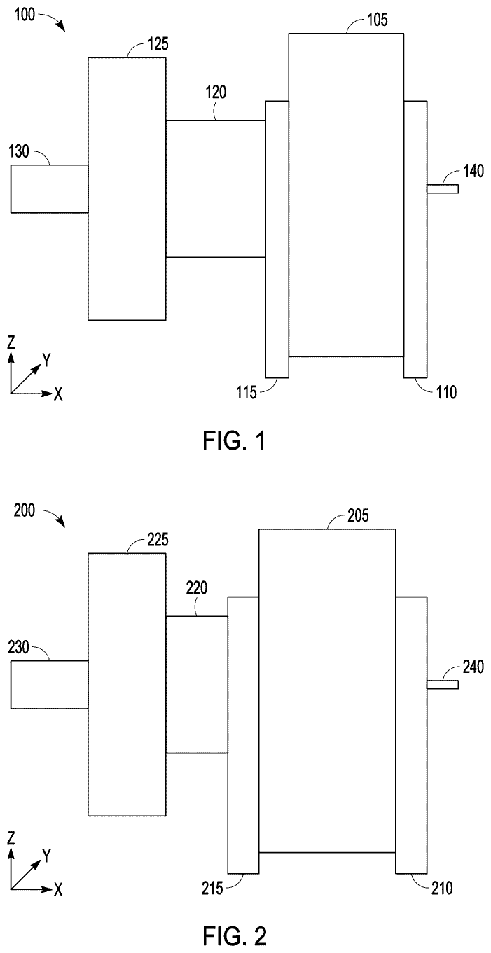

FIG. 1 represents components of a memory cell 100 having a double sided high-k blocking dielectric. Memory cell 100 can include a charge trap region 120 and a blocking dielectric separating charge trap region from access 140 to a control gate for the memory cell. The access 140 can be the control gate. The blocking dielectric can include a wide bandgap dielectric 105 sandwiched between a first high-k dielectric 115 and a second high-k dielectric 110. First high-k dielectric 115 can be structured between and contacting charge trap region 120 and wide bandgap dielectric 105. First high-k dielectric 115 contacts a first side of wide bandgap dielectric 105 and second high-k dielectric 110 contacts wide bandgap dielectric 105 on a second side of wide bandgap dielectric 105 opposite the first side.

Variations of memory cell 100 or memory cells similar to memory cell 100 can include a number of different embodiments that may be combined depending on the application of such memory cells or the architecture or process flow of an integrated circuit for which such memory cells are implemented. Such memory cells can include first high-k dielectric 115 and second high-k dielectric 110 having the same composition. The composition can be, but is not limited to, aluminum oxide. Other high-k dielectrics that can be used for first high-k dielectric 115 or second high-k dielectric 110 can include one or more of hafnium oxide, zirconium oxide, or other dielectric having a dielectric constant greater than aluminum oxide. First high-k dielectric 115 can have a thickness within a window of thicknesses, where the window has a border defined corresponding to a read disturb or program threshold and a border defined corresponding to a data retention threshold. First high-k dielectric 115 can have a thickness corresponding to a midpoint between a thickness corresponding to a specified read disturb or program threshold and a thickness corresponding to a specified data retention threshold. Second high-k dielectric 110 can have, but is not limited to, the same thickness as first high-k dielectric 115. The thresholds can depend on the structure or operational parameters of the memory device to have a double sided high-k blocking dielectric or the application of the memory device. Wide bandgap dielectric 105 can be silicon oxide or other dielectric having a wide bandgap appropriate for relatively high voltage applied that is implemented in programming memory cell 100.

Charge trap region 120 can include, but is not limited to, silicon nitride. Charge trap region 120 can be separated from a channel structure 130 for memory cell 100 by a BE dielectric 125 between charge trap region 120 and channel structure 130 of memory cell 100. The blocking dielectric of wide bandgap dielectric 105 sandwiched between first high-k dielectric 115 and second high-k dielectric 110 can extend vertically adjacent charge trap region 120. The components of memory cell 100 shown in FIG. 1 are not limited in the vertical directions shown. The vertical extent of each of the individual components can depend on the application of the architecture shown in FIG. 1. Contacts to the memory cell 100 are not shown to focus on the components of memory cell 100. The architecture of channel structure 130 can be used as transistor in other applications.

FIG. 2 represents components of a memory cell 200 having a double sided high-k blocking dielectric. Memory cell 200 can include a charge trap region 220 and a blocking dielectric separating charge trap region from access 240 to a control gate for the memory cell. The access 240 can be the control gate. The blocking dielectric can include a wide bandgap dielectric 205 sandwiched between a first high-k dielectric 215 and a second high-k dielectric 210. First high-k dielectric 215 can be structured between and contacting charge trap region 220 and wide bandgap dielectric 205. First high-k dielectric 215 contacts a first side of wide bandgap dielectric 205 and second high-k dielectric 210 contacts wide bandgap dielectric 205 on a second side of wide bandgap dielectric 205 opposite the first side.

Variations of memory cell 200 or memory cells similar to memory cell 200 can include a number of different embodiments that may be combined depending on the application of such memory cells or the architecture or process flow of an integrated circuit for which such memory cells are implemented. Such memory cells can include first high-k dielectric 215 and second high-k dielectric 210 having the same composition. The composition can be, but is not limited to, aluminum oxide. Other high-k dielectrics that can be used for first high-k dielectric 215 or second high-k dielectric 210 can include one or more of hafnium oxide, zirconium oxide, or other dielectric having a dielectric constant greater than aluminum oxide. First high-k dielectric 215 can have a thickness within a window of thicknesses, where the window has a border defined corresponding to a read disturb or program threshold and a border defined corresponding to a data retention threshold. First high-k dielectric 215 can have a thickness corresponding to a midpoint between a thickness corresponding to a specified read disturb or program threshold and a thickness corresponding to a specified data retention threshold. Second high-k dielectric 210 can have, but is not limited to, the same thickness as first high-k dielectric 215. The thresholds can depend on the structure or operational parameters of the memory device to have a double sided high-k blocking dielectric or the application of the memory device. Wide bandgap dielectric 205 can be silicon oxide or other dielectric having a wide bandgap appropriate for relatively high voltage applied in programming memory cell 200.

Charge trap region 220 can include, but is not limited to, silicon nitride. Charge trap region 220 can be separated from a channel structure 230 for memory cell 200 by a BE dielectric 225 between charge trap region 220 and channel structure 230 of memory cell 200. The blocking dielectric of wide bandgap dielectric 205 sandwiched between first high-k dielectric 215 and second high-k dielectric 210 can extend vertically adjacent charge trap region 220. The components of memory cell 200 shown in FIG. 2 are not limited in the vertical directions shown. The vertical extent of each of the individual components can depend on the application of the architecture shown in FIG. 2. Contacts to the memory cell 200 are not shown to focus on the components of memory cell 200. The architecture of channel structure 230 can be used as transistor in other applications.

Though memory cell 100 and memory cell 200 are not shown to scale in FIGS. 1 and 2, respectively, differences in the two memory cells are shown. The architecture of memory cell 200 differs from that of memory cell 100 of FIG. 1 in that charge trap region 220 is thinner than charge trap region 120, while wide bandgap dielectric 205, first high-k dielectric 215, and second high-k dielectric 210 are thicker than wide bandgap dielectric 105, first high-k dielectric 115, and second high-k dielectric 110. The overall thickness in the horizontal direction of memory cell 200 and memory cell 100 can be the same. The selection of the material of the high-k dielectrics can provide the EOT for the given physical thickness to allow for appropriate scaling within the chip in which the device containing the memory cell is integrated. First high-k dielectric 115 or 215 or second high-k dielectric 110 or 210 can have a thickness that is one-tenth of the thickness of wide bandgap dielectric 105 or 205 or less.

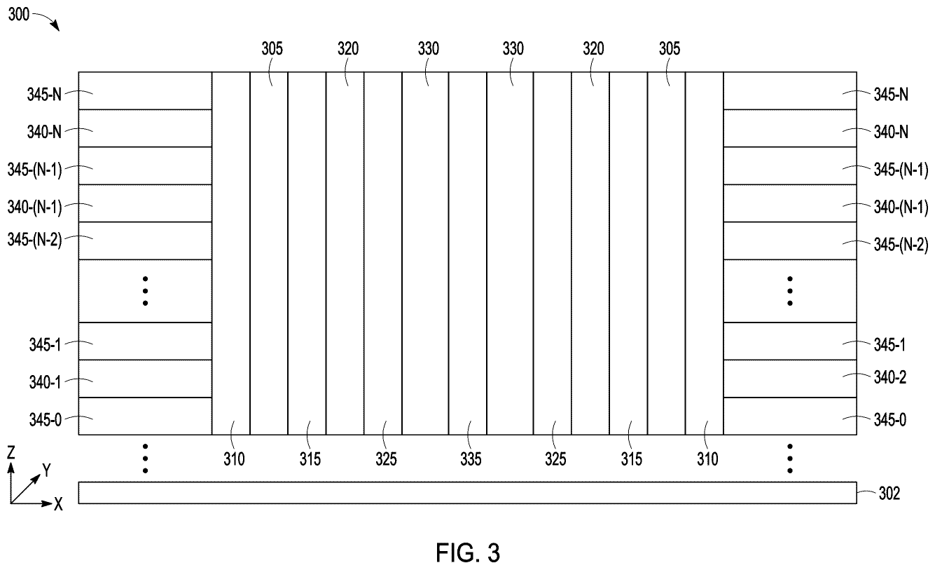

FIG. 3 represents a view of a memory device 300 having a string of memory cells. The memory cells can be structured about a gap fill 335. Memory device 300 can include a pillar extending vertically above a substrate 302, where the pillar has multiple tiers of memory cells. Each memory cell can structured as discussed with memory cell 100 of FIG. 1, memory cell 200 of FIG. 2, or similar memory cell. Each memory cell of the pillar can include a charge trap region 320 and a blocking oxide separating the charge trap region 320 from a control gate. The blocking oxide can have a first high-k dielectric 310 on and contacting a first side of a wide bandgap dielectric region 305 and a second high-k dielectric 315 on and contacting a second side of wide bandgap dielectric region 305 opposite the first side. The wide bandgap dielectric region 305 can be a silicon oxide region such as, but not limited to, a silicon dioxide region. First high-k dielectric 310 and second high-k dielectric 315 can have a common composition. The common composition can include one or more of aluminum oxide, hafnium oxide, zirconium oxide, or other appropriate high-k dielectric.

In the architecture of memory device 300, the memory cells are a portion of N tiers of memory cells, where the memory cells are stacked and have control gates 340-1 . . . 340-(N−1), and 340-N, respectively, separated from each other by an electrical insulation region. For example, control gate 340-N is bounded by electrical isolation regions 345-N and 345-(N−1). Control gate 340-(N−1) is bounded by electrical isolation regions 345-(N−1) and 345-(N−2). Control gate 340-1 is bounded by electrical isolation regions 345-1 and 345-0. The material of first high-k dielectric 310 for each memory cell can extend vertically on and contacting each of control gates 340-1 . . . 340-(N−1), and 340-N and separating electrical isolation regions 345-0 . . . 345-5 and can extend vertically on and contacting material for wide bandgap dielectric region 305 that can extend vertically in the pillar. The material of second high-k dielectric 315 for each memory cell can extend vertically on and contacting material for wide bandgap dielectric region 305 and can extend vertically on and contacting material for charge trap region 320 that can extend vertically in the pillar. The material for charge trap region 320 is separated from material for a channel structure 330, which can extend vertically in the pillar, by material for a tunnel region 325 that can extend vertically in the pillar. Tunnel region 325 can be BE tunnel region. The materials for first high-k dielectric 310, wide bandgap dielectric region 305, second high-k dielectric 315, charge trap region 320, tunnel region 325, and channel structure 330 can extend vertically at least from a bottommost memory cell to and including a topmost memory cell of the pillar about gap fill 335.

In the sandwich architecture of a blocking dielectric, first high-k dielectric 310 or second high-k dielectric 315 can have a thickness within a window of thicknesses, where the window has a border defined corresponding to a read disturb or program threshold and a border defined corresponding to a data retention threshold for the memory cells. First high-k dielectric 310 or second high-k dielectric 315 can have a thickness corresponding to a midpoint between a thickness corresponding to a specified read disturb or program threshold and a thickness corresponding to a specified data retention threshold. First high-k dielectric 310 can second high-k dielectric 315 can have the same composition or the same thickness. Each memory cell containing a blocking dielectric having a high-k dielectric sandwich can be a M LC such as, but not limited to, a TLC or a QLC.

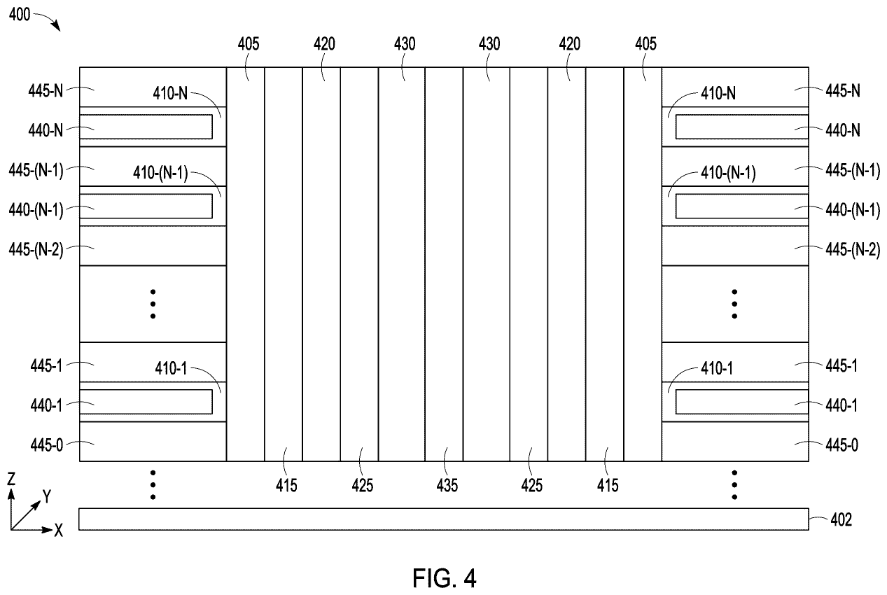

FIG. 4 represents a view of a memory device 400 having a string of memory cells. The memory cells can be structured about a gap fill 435. Memory device 400 can include a pillar extending vertically above a substrate 402, where the pillar has multiple tiers of memory cells. Each memory cell of the pillar can include a charge trap region 420 and a blocking oxide separating charge trap region 420 from a control gate. The blocking oxide of a jth memory cell (1≤j≤N) can have a first high-k dielectric 410-j on and contacting a first side of a wide bandgap dielectric region 405 and a second high-k dielectric 415 on and contacting a second side of wide bandgap dielectric region 405 opposite the first side. Each first high-k dielectric of the set of first high-k dielectrics 410-1 . . . 410-N can be located individually on and contacting a corresponding control gate 440-1 . . . 440-N, respectively, for an individual memory cell. The wide bandgap dielectric region 405 can be, but is not limited to, a silicon oxide region such as a silicon dioxide region. The set of first high-k dielectric 410-1 . . . 410-N and second high-k dielectric 415 can have a common composition or a common thickness. The common composition can include one or more of aluminum oxide, hafnium oxide, zirconium oxide, or other appropriate high-k dielectric.

In the architecture of memory device 400, the memory cells are a portion of N tiers of memory cells, where the memory cells are stacked and have control gates 440-1 . . . 440-(N−1), and 440-N, respectively, separated from each other by an electrical insulation region. In addition, control gate 440-j and high-k dielectric 410-j, for (1≤j≤N), can be structured as a pair of regions. For example, control gate 440-N is bounded by electrical isolation regions 445-N and 445-(N−1). High_k dielectric 410-N can be positioned on at least a portion of a horizontal surface of control gate 440-N separating control gate 440-N from electrical isolation region 445-N and on at least a portion of a horizontal surface of control gate 440-N separating control gate 440-N from electrical isolation region 445-(N−1), along with being positioned on a vertical surface of control gate 440-N separating control gate 440-N from wide bandgap region 405. High-k dielectric 410-N can be structured without substantially contacting vertical surfaces of electrical isolation regions 445-N and 445-(N−1). Control gate 440-(N−1) is bounded by electrical isolation regions 445-(N−1) and 445-(N−2). High_k dielectric 410-(N−1) can be positioned on at least a portion of a horizontal surface of control gate 440-(N−1) separating control gate 410-(N−1) from electrical isolation region 445-(N−1) and on at least a portion of a horizontal surface of control gate 440-N separating control gate 440-N from electrical isolation region 445-(N−2), along with being positioned on a vertical surface of control 440-(N−1) separating control gate 440-(N−1) from wide bandgap region 405. High-k dielectric 410-(N−1) can be structured without substantially contacting vertical surfaces of electrical isolation regions 445-(N−1) and 445-(N−2).

Control gate 440-1 is bounded by electrical isolation regions 445-1 and 445-0. High_k dielectric 410-(N−1) can be positioned on at least a portion of a horizontal surface of control gate 440-1 separating control gate 440-1 from electrical isolation region 445-1 and on at least a portion of a horizontal surface of control gate 440-1 separating control gate 440-1 from electrical isolation region 445-0, along with being positioned on a vertical surface of control gate 440-1 separating control gate 440-1 from wide bandgap region 405. High-k dielectric 410-1 can be structured without substantially contacting vertical surfaces of electrical isolation regions 445-1 and 445-0.

The material of second high-k dielectric 415 for each memory cell can extend vertically on and contacting material for wide bandgap dielectric region 405 and can extend vertically on and contacting material for charge trap region 420 that can extend vertically in the pillar. The material charge trap region 420 can be separated from material for a channel structure 430, which can extend vertically in the pillar, by material for a tunnel region 425 that can extend vertically in the pillar. Tunnel region 425 can be a BE tunnel region. The materials for wide bandgap dielectric region 405, second high-k dielectric 415, charge trap region 420, tunnel region 425, and channel structure 430 can extend vertically at least from a bottommost memory cell to and including a topmost memory cell of the pillar about gap fill 435.

In the sandwich architecture of a blocking dielectric, first high-k dielectric 410-j (1≤j≤N) or second high-k dielectric 415 can have a thickness within a window of thicknesses, where the window has a border defined corresponding to a read disturb or program threshold and a border defined corresponding to a data retention threshold for the memory cells. First high-k dielectric 410-j (1≤j≤N) or second high-k dielectric 415 can have a thickness corresponding to a midpoint between a thickness corresponding to a specified read disturb or program threshold and a thickness corresponding to a specified data retention threshold. One or more of first high-k dielectric 410-j (1≤j≤N) and second high-k dielectric 415 can have the same composition or the same thickness. Each memory cell containing a blocking dielectric having a high-k dielectric sandwich can be a MLC such as, but not limited to, a TLC or a QLC.

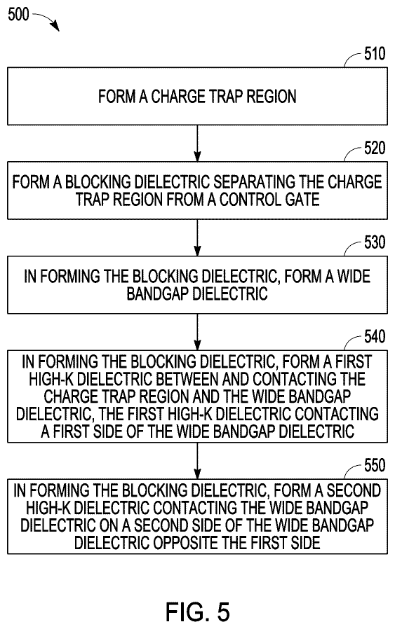

FIG. 5 shows a flow diagram of an embodiment of an example method 500 of forming a memory cell. At 510, a charge trap region is formed. At 520, a blocking dielectric is formed separating the charge trap region from a control gate. At 530, in forming the blocking dielectric, a wide bandgap dielectric is formed. At 540, in forming the blocking dielectric, a first high-k dielectric is formed between and contacting the charge trap region and the wide bandgap dielectric, the first high-k dielectric contacting a first side of the wide bandgap dielectric. At 550, in forming the blocking dielectric, a second high-k dielectric is formed contacting the wide bandgap dielectric on a second side of the wide bandgap dielectric opposite the first side.

Variations of method 500 or methods similar to method 500 can include a number of different embodiments that may be combined depending on the application of such methods or the architecture or process flow of an integrated circuit for which such methods are implemented. Such methods can include forming the memory cell as part of the formation of a memory device. The memory cell can be formed as one of multiple memory cells arranged as tiers in a pillar extending vertically above a substrate in the memory device.

Variations of method 500 or methods similar to method 500 can include forming the first high-k dielectric and the second high-k dielectric having substantially the same composition. Substantially the same composition can include small variations in stoichiometries of the compositions for the first high-k dielectric and the second high-k dielectric. The first high-k dielectric can be formed with a thickness corresponding to a midpoint between performance with respect to a read disturb and performance with respect to data retention. The thickness of the first high-k dielectric and the thickness of the second high-k dielectric can be formed with thicknesses corresponding to a midpoint between performance with respect to a read disturb and performance with respect to data retention.

Variations of method 500 can be performed in construction other components of the memory cell. Forming the charge trap region can include forming silicon nitride with a bandgap engineered dielectric separating the silicon nitride from a channel structure for the memory cell. The wide bandgap dielectric of the memory cell can be formed by forming silicon oxide. The first high-k dielectric and the second high-k dielectric can be formed by forming one or more of aluminum oxide, hafnium oxide, or zirconium oxide. The forming of the components discussed with respect to method 500 or similar methods are not limited to forming the components in a specfic order.

Various deposition techniques for forming components of memory cells 100 and 200 of FIG. 1 and FIG. 2, respectively, and memory devices 300 and 400 of FIGS. 3 and 4, respectively, and methods associated with FIG. 5 can be used that are appropriate for the material being formed, the dimensions of the material being formed, and the architecture in which the material is being formed. Processes for forming the various materials can include, but are not limited to, chemical vapor deposition (CVD), atomic layer deposition (ALD), and physical vapor deposition (PVD). PVD can include, but is not limited to, sputtering, ion beam deposition, electron beam evaporation, pulsed laser deposition, and vacuum arc methods, among others. CVD can include, but is not limited to, plasma chemical vapor deposition and laser chemical vapor deposition, among others. Selective etching and conventional masking techniques can be used to remove selected regions in the processing. Selective etching is a process in which one or more materials are removed from a structure, while one or more other materials remain in the structure with no or little removal. Selective etching can depend on the material to be etched, the material not to be etched, the etchant employed, and the method for etching. Etching procedures can include, but are not limited to, wet etching, dry etching, and atomic layer etching deposition, among others, where each of these basic methods include a number of different etching procedures.

Electronic devices, such as mobile electronic devices (e.g., smart phones, tablets, etc.), electronic devices for use in automotive applications (e.g., automotive sensors, control units, driver-assistance systems, passenger safety or comfort systems, etc.), and Internet-connected appliances or devices (e.g., Internet-of-Things (IoT) devices, etc.), have varying storage needs depending on, among other things, the type of electronic device, use environment, performance expectations, etc. Electronic devices can be broken down into several main components: a processor (e.g., a central processing unit (CPU) or other main processor); memory (e.g., one or more volatile or non-volatile RAM memory device, such as DRAM, mobile or low-power double-data-rate synchronous DRA M (DDR SDRAM), etc.); and a storage device (e.g., non-volatile memory (NVM) device, such as flash memory, ROM, an SSD, an MMC, or other memory card structure or assembly, etc.). In certain examples, electronic devices can include a user interface (e.g., a display, touch-screen, keyboard, one or more buttons, etc.), a graphics processing unit (GPU), a power management circuit, a baseband processor or one or more transceiver circuits, etc.

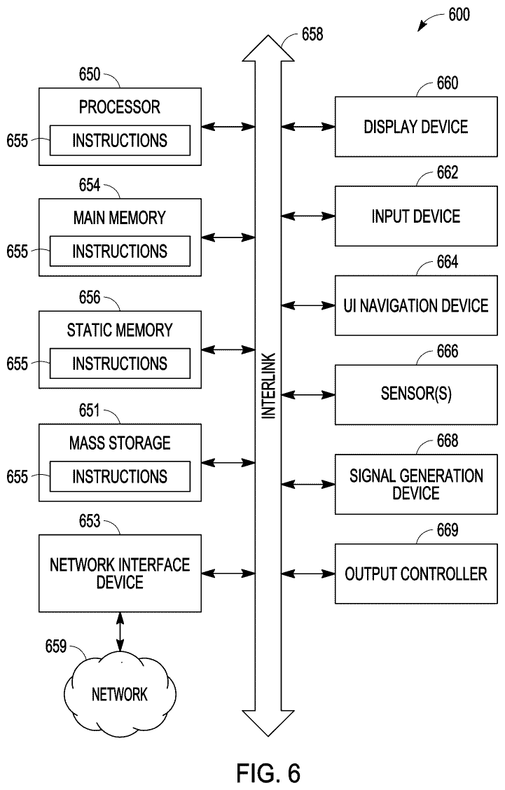

FIG. 6 illustrates a block diagram of an example machine 600 having one or more memory devices, where such memory devices include one or more memory cells containing a blocking dielectric separating a charge trap region from a control gate in which the blocking dielectric includes a high-k dielectric between and contacting a wide bandgap dielectric and the charge trap region. Another high-k dielectric can be positioned contacting the wide bandgap dielectric on a side of the wide bandgap dielectric opposite the side on which the first high-k dielectric is positioned, forming a sandwiched structure. The machine 600, having one or more such memory devices, may operate as a standalone machine or may be connected, for example networked, to other machines.

In a networked deployment, the machine 600 may operate in the capacity of a server machine, a client machine, or both in server-client network environments. In an example, the machine 600 may act as a peer machine in peer-to-peer (P2P) (or other distributed) network environment. The machine 600 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (Saas), other computer cluster configurations. The example machine 600 can be arranged to operate with one or more memory devices having memory cells with double-sided high-k blocking dielectrics as taught herein.

The machine (e.g., computer system) 600 may include a hardware processor 650 (e.g., a CPU, a GPU, a hardware processor core, or any combination thereof), a main memory 654, and a static memory 656, some or all of which may communicate with each other via an interlink (e.g., bus) 658. The machine 600 may further include a display device 660, an alphanumeric input device 662 (e.g., a keyboard), and a user interface (UI) navigation device 664 (e.g., a mouse). In an example, the display device 660, input device 662, and UI navigation device 664 may be a touch screen display. The machine 600 may additionally include a mass storage device (e.g., drive unit) 651, a signal generation device 668 (e.g., a speaker), a network interface device 653, and one or more sensors 666, such as a global positioning system (GPS) sensor, compass, accelerometer, or other sensor. The machine 600 may include an output controller 669, such as a serial (e.g., USB, parallel, or other wired or wireless (e.g., infrared (IR), near field communication (NFC), etc.) connection to communicate or control one or more peripheral devices (e.g., a printer, card reader, etc.).

The machine 600 may include machine-readable media on which is stored one or more sets of data structures or instructions 655 (e.g., software) embodying or utilized by the machine 600 to perform any one or more of the techniques or functions for which the machine 600 is designed. The machine-readable media can include main memory 654, static memory 656, or mass storage device 651. The instructions 655 may reside, completely or at least partially, within main memory 654, within static memory 656, within the mass storage device 651, or within the hardware processor 650 during execution thereof by the machine 600.

While each of the machine-readable media is illustrated as a single medium, the term “machine-readable medium” may include a single medium or multiple media (e.g., a centralized or distributed database, or associated caches and servers) configured to store the one or more instructions 655. The term “machine-readable medium” may include any medium that is capable of storing or holding instructions for execution by the machine 600 and that cause the machine 600 to perform any one or more of the techniques to which the machine 600 is designed, or that is capable of storing or holding data structures used by or associated with such instructions. Non-limiting machine-readable medium examples may include solid-state memories, optical and magnetic media, or other tangible structures. Examples of machine-readable media can include: non-volatile memory, such as semiconductor memory devices (e.g., EPROM, EEPROM) and flash memory devices; magnetic disks, such as internal hard disks and removable disks; magneto-optical disks; and compact disc-ROM (CD-ROM) and digital versatile disc-read only memory (DVD-ROM) disks.

The instructions 655 (e.g., software, programs, an operating system (OS), etc.) or other data, stored on the mass storage device 651, can be accessed by the main memory 654 for use by the processor 650. The main memory 654 (e.g., DRAM) is typically fast, but volatile, and thus a different type of storage than the mass storage device 651 (e.g., an SSD), which is suitable for long-term storage, including while in an “off” condition. The instructions 655 or data in use by a user or the machine 600 are typically loaded in the main memory 654 for use by the processor 650. When the main memory 654 is full, virtual space from the mass storage device 651 can be allocated to supplement the main memory 654; however, because the mass storage device 651 is typically slower than the main memory 654, and write speeds are typically at least twice as slow as read speeds, use of virtual memory can greatly reduce user experience due to storage device latency (in contrast to the main memory 654, e.g., DRAM). Further, use of the mass storage device 651 for virtual memory can greatly reduce the usable lifespan of the mass storage device 651.

Storage devices optimized for mobile electronic devices, or mobile storage, traditionally include MMC solid-state storage devices (e.g., micro Secure Digital (microSD™) cards, etc.). MMC devices include a number of parallel interfaces (e.g., an 8-bit parallel interface) with a host device and are often removable and separate components from the host device. In contrast, eMMC™ devices are attached to a circuit board and considered a component of the host device, with read speeds that rival SATA-based SSD devices. However, demand for mobile device performance continues to increase, such as to fully enable virtual or augmented-reality devices, utilize increasing networks speeds, etc. In response to this demand, storage devices have shifted from parallel to serial communication interfaces. UFS devices, including controllers and firmware, communicate with a host device using a low-voltage differential signaling (LVDS) serial interface with dedicated read/write paths, further advancing greater read/write speeds.

The instructions 655 may further be transmitted or received over a communications network 659 using a transmission medium via the network interface device 653 utilizing any one of a number of transfer protocols (e.g., frame relay, Internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, peer-to-peer (P2P) networks, among others. In an example, the network interface device 653 may include one or more physical jacks (e.g., Ethernet, coaxial, or phone jacks) or one or more antennas to connect to the communications network 659. In an example, the network interface device 653 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any tangible medium that is capable of carrying instructions to and for execution by the machine 600, and includes instrumentalities to propagate digital or analog communications signals to facilitate communication of such instructions, which instructions may be implemented by software.

The following are example embodiments of devices and methods, in accordance with the teachings herein.

An example memory cell 1 can comprise a charge trap region and a blocking dielectric separating the charge trap region from a control gate. The blocking dielectric includes a wide bandgap dielectric; a first high-k dielectric between and contacting the charge trap region and the wide bandgap dielectric, the first high-k dielectric contacting a first side of the wide bandgap dielectric; and a second high-k dielectric contacting the wide bandgap dielectric on a second side of the wide bandgap dielectric opposite the first side.

An example memory cell 2 can include features of example memory cell 1 and can include the first high-k dielectric and the second high-k dielectric having a common composition.

An example memory cell 3 can include features of example memory cell 2 and any of the preceding example memory cells and can include the common composition to include aluminum oxide.

An example memory cell 4 can include features of any of the preceding example memory cells and can include the first high-k dielectric having a thickness within a window of thicknesses, the window having a border defined corresponding to a read disturb or program threshold and a border defined corresponding to a data retention threshold.

An example memory cell 5 can include features of any of the preceding example memory cells and can include the first high-k dielectric having a thickness corresponding to a midpoint between a thickness corresponding to a specified read disturb or program threshold and a thickness corresponding to a specified data retention threshold.

An example memory cell 6 can include features of any of the preceding example memory cells and can include the charge trap region to include silicon nitride.

An example memory cell 7 can include features of any of the preceding example memory cells and can include the memory cell to include a BE dielectric between the charge trap region and a channel structure of the memory cell.

An example memory cell 8 can include features of any of the preceding example memory cells and can include the blocking dielectric extending vertically adjacent the charge trap region.

In an example memory cell 9, any of the memory cells of example memory cells 1 to 8 may include components incorporated into an electronic apparatus further comprising one or more host processors and a communication bus extending between the one or more host processors and the memory cell.

In an example memory cell 10, any of the memory cells of example memory cells 1 to 9 may be modified to include any structure presented in another of example memory cell 1 to 9.

In an example memory cell 11, any apparatus associated with the memory cells of example memory cells 1 to 10 may further include a machine-readable storage device configured to store instructions as a physical state, wherein the instructions may be used to perform one or more operations of the apparatus.

In an example memory cell 12, any of the memory cells of example memory cells 1 to 6 may be operated in accordance with any of the below example methods 1 to 9.

An example memory device 1 can comprise pillars extending vertically above a substrate, each of the pillars having multiple tiers of memory cells. Each memory cell includes a charge trap region; a blocking oxide separating the charge trap region from a control gate, the blocking oxide having a first high-k dielectric on and contacting a first side of a silicon oxide region and a second high-k dielectric on and contacting a second side of the silicon oxide region opposite the first side.

An example memory device 2 can include features of example memory device 1 and can include the first high-k dielectric and the second high-k dielectric having a common composition.

An example memory device 3 can include features of memory device 2 and any of the preceding example memory devices and can include the common composition to include one or more of aluminum oxide, hafnium oxide, or zirconium oxide.

An example memory device 4 can include features of any of the preceding example memory devices and can include the first high-k dielectric having a thickness within a window of thicknesses, the window having a border defined corresponding to a read disturb or program threshold and a border defined corresponding to a data retention threshold.

An example memory device 5 can include features of any of the preceding example memory devices and can include the first high-k dielectric having a thickness corresponding to a midpoint between a thickness corresponding to a specified read disturb or program threshold and a thickness corresponding to a specified data retention threshold.

An example memory device 6 can include features of any of the preceding example memory devices and can include each memory cell of a pillar to include a bandgap engineered dielectric between the charge trap region and a cell channel structure of the memory cell, the cell channel structure being a portion of a channel structure that extends vertically at least from a bottommost memory cell to and including a topmost memory cell of the pillar.

An example memory device 7 can include features of any of the preceding example memory devices and can include each memory cell being a triple-level cell or a quad-level cell.

In an example memory device 8, any of the memory devices of example memory devices 1 to 7 may include memory devices incorporated into an electronic apparatus further comprising a host processor or memory controller and a communication bus extending between the host processor/memory controller and the memory device.

In an example memory device 9, any of the memory devices of example memory devices 1 to 8 may be modified to include any structure presented in another of example memory device 1 to 8.

In an example memory device 10, any apparatus associated with the memory devices of example memory devices 1 to 9 may further include a machine-readable storage device configured to store instructions as a physical state, wherein the instructions may be used to perform one or more operations of the apparatus.

In an example memory device 11, any of the memory devices of example memory devices 1 to 10 may be operated in accordance with any of the below example methods 1 to 9.

An example method 1 can comprise forming a memory cell including forming a charge trap region; forming a blocking dielectric separating the charge trap region from a control gate. Forming the blocking dielectric includes: forming a wide bandgap dielectric; forming a first high-k dielectric between and contacting the charge trap region and the wide bandgap dielectric, the first high-k dielectric contacting a first side of the wide bandgap dielectric; and forming a second high-k dielectric contacting the wide bandgap dielectric on a second side of the wide bandgap dielectric opposite the first side.

An example method 2 can include features of example method 1 and can include forming the memory cell as one of multiple memory cells arranged as tiers in a pillar extending vertically above a substrate in a memory device.

An example method 3 can include features of any of the preceding example methods and can include forming the first high-k dielectric and the second high-k dielectric having substantially the same composition.

An example method 4 can include features of any of the preceding example methods and can include forming the first high-k dielectric with a thickness corresponding to a midpoint between performance with respect to a read disturb and performance with respect to data retention.

An example method 5 can include features of any of the preceding example methods and can include forming the charge trap region to include forming silicon nitride with a BE engineered dielectric separating the silicon nitride from a channel structure for the memory cell; forming the wide bandgap dielectric by forming silicon oxide; and forming the first high-k dielectric and the second high-k dielectric by forming one or more of aluminum oxide, hafnium oxide, or zirconium oxide.

In an example method 6, any of the example methods 1 to 5 may be performed in forming an electronic apparatus further comprising a host processor and a communication bus extending between the host processor and a memory system.

In an example method 7, any of the example methods 1 to 6 may be modified to include operations set forth in any other of example methods 1 to 6.

In an example method 8, any of the example methods 1 to 7 may be implemented at least in part through use of instructions stored as a physical state in one or more machine-readable storage devices.

An example method 9 can include features of any of the preceding example methods 1 to 8 and can include performing functions associated with any features of example memory cells 1 to 12 and example memory devices 1 to 11.

An example machine-readable storage device storing instructions, that when executed by one or more processors, cause a machine to perform operations, can comprise instructions to perform functions associated with any features of example memory cells 1 to 12, example memory devices 1 to 11 or perform methods associated with any features of example methods 1 to 9.

Although specific embodiments have been illustrated and described herein, it will be appreciated by those of ordinary skill in the art that any arrangement that is calculated to achieve the same purpose may be substituted for the specific embodiments shown. Various embodiments use permutations and/or combinations of embodiments described herein. The above description is intended to be illustrative, and not restrictive, and the phraseology or terminology employed herein is for the purpose of description. In addition, in the foregoing Detailed Description, it can be seen that various features are grouped together in a single embodiment for the purpose of streamlining the disclosure. Combinations of the above embodiments and other embodiments will be apparent to those of skill in the art upon studying the above description.

What is claimed is:

1. A memory cell comprising:
a charge trap region; and
a blocking dielectric separating the charge trap region from a control gate, the blocking dielectric including:
a wide bandgap dielectric;
a first high-k dielectric between and contacting the charge trap region and
the wide bandgap dielectric, the first high-k dielectric contacting a first side of the wide bandgap dielectric; and
a second high-k dielectric contacting the wide bandgap dielectric on a second side of the wide bandgap dielectric opposite the first side.

2. The memory cell of claim 1, wherein the first high-k dielectric and the second high-k dielectric have a common composition.

3. The memory cell of claim 2, wherein the common composition includes aluminum oxide.

4. The memory cell of claim 1, wherein the first high-k dielectric has a thickness within a window of thicknesses, the window having a border defined corresponding to a read disturb or program threshold and a border defined corresponding to a data retention threshold.

5. The memory cell of claim 1, wherein the first high-k dielectric has a thickness corresponding to a midpoint between a thickness corresponding to a specified read disturb or program threshold and a thickness corresponding to a specified data retention threshold.

6. The memory cell of claim 1, wherein the charge trap region includes silicon nitride.

7. The memory cell of claim 1, wherein the memory cell includes a bandgap engineered dielectric between the charge trap region and a channel structure of the memory cell.

8. The memory cell of claim 1, wherein the blocking dielectric extends vertically adjacent the charge trap region.

9. A memory device comprising:
pillars extending vertically above a substrate, each of the pillars having multiple tiers of memory cells, each memory cell including:
a charge trap region;
a blocking oxide separating the charge trap region from a control gate, the blocking oxide having a first high-k dielectric on and contacting a first side of a silicon oxide region and a second high-k dielectric on and contacting a second side of the silicon oxide region opposite the first side.

10. The memory device of claim 9, wherein the first high-k dielectric and the second high-k dielectric have a common composition.

11. The memory device of claim 10, wherein the common composition includes one or more of aluminum oxide, hafnium oxide, or zirconium oxide.

12. The memory device of claim 9, wherein the first high-k dielectric has a thickness within a window of thicknesses, the window having a border defined corresponding to a read disturb or program threshold and a border defined corresponding to a data retention threshold.

13. The memory device of claim 9, wherein the first high-k dielectric has a thickness corresponding to a midpoint between a thickness corresponding to a specified read disturb or program threshold and a thickness corresponding to a specified data retention threshold.

14. The memory device of claim 9, wherein each memory cell of a pillar includes a bandgap engineered dielectric between the charge trap region and a cell channel structure of the memory cell, the cell channel structure being a portion of a channel structure that extends vertically at least from a bottommost memory cell to and including a topmost memory cell of the pillar.

15. The memory device of claim 9, wherein each memory cell is a triple-level cell or a quad-level cell.

16. A method comprising:
forming a memory cell including:
forming a charge trap region; and
forming a blocking dielectric separating the charge trap region from a control gate, forming the blocking dielectric including:
forming a wide bandgap dielectric;
forming a first high-k dielectric between and contacting the charge trap region and the wide bandgap dielectric, the first high-k dielectric contacting a first side of the wide bandgap dielectric; and
forming a second high-k dielectric contacting the wide bandgap dielectric on a second side of the wide bandgap dielectric opposite the first side.

17. The method of claim 16, wherein the method includes forming the memory cell as one of multiple memory cells arranged as tiers in a pillar extending vertically above a substrate in a memory device.

18. The method of claim 16, wherein the method includes forming the first high-k dielectric and the second high-k dielectric having substantially the same composition.

19. The method of claim 16, wherein the method includes forming the first high-k dielectric with a thickness corresponding to a midpoint between performance with respect to a read disturb and performance with respect to data retention.

20. The method of claim 16, wherein the method includes:
forming the charge trap region includes forming silicon nitride with a bandgap engineered dielectric separating the silicon nitride from a channel structure for the memory cell;
forming the wide bandgap dielectric by forming silicon oxide; and
forming the first high-k dielectric and the second high-k dielectric by forming one or more of aluminum oxide, hafnium oxide, or zirconium oxide.
